(19) United States
(12) Patent Application Publication
(10) Pub. No.: US 2026/0001806 A1
(43) Pub. Date: Jan. 1, 2026

(54) METHOD FOR MANUFACTURING GLASS PLATE INCLUDING FUNCTIONAL LAYER AND FUNCTIONAL LAYER FORMING DEVICE

(71) Applicant: NIPPON SHEET GLASS COMPANY, LIMITED, Tokyo (JP)

(72) Inventors: Keiko TSURI, Northwood, OH (US); Takako MORIOKA, Tokyo (JP); Tasuku MORIMOTO, Tokyo (JP); Hiroaki KOMINAMI, Tokyo (JP); Ryo ANRAKU, Tokyo (JP); Satoshi TANAKA, Tokyo (JP); Steven Edward PHILLIPS, Ottawa, IL (US)

(21) Appl. No.: 18/760,236

(22) Filed: Jul. 1, 2024

(51) Int. Cl. C03C 17/00; C03B 18/14; C23C 16/448

(52) U.S. Cl. CPC C03C 17/002; C03B 18/14; C23C 16/4486; C03C 2218/152

(57) ABSTRACT

There is demand for a method and a device that can increase types of functional layers that can be formed on a glass plate by expanding the scope of applicable raw materials. A method for manufacturing a glass plate including a functional layer in which the functional layer is formed on a first main surface of the glass plate including the first main surface and a second main surface, the method including: a preparation step (#21) of preparing the glass plate; a conveying step (#22) of conveying a mist substance for forming the functional layer to a position facing the first main surface with use of a carrier gas; a supplying step (#24) of supplying the mist substance from the position facing the first main surface toward the first main surface; and a functional layer forming step (#25) of forming the functional layer on the first main surface.

### BACKGROUND OF THE INVENTION

### 1. Field of the Invention

The present invention relates to a method for manufacturing a glass plate including a functional layer and a functional layer forming device.

### 2. Description of the Related Art

Techniques for forming a functional layer such as a transparent conductive film on a main surface of a glass plate with use of a CVD method or the like are conventionally known. JP 2014-80644A is an example of related art.

### SUMMARY OF THE INVENTION

However, in the conventional methods, it is necessary to make a gas of a raw material of the functional layer and applicable raw materials are limited, and accordingly, types of functional layers that can be formed on a glass plate are limited.

Under the above circumstances, there is demand for a method and a device that can expand the scope of applicable raw materials and increase the types of functional layers that can be formed on a glass plate.

A method for manufacturing a glass plate including a functional layer according to the present invention is a method for manufacturing a glass plate including a functional layer in which the functional layer is formed on a first main surface of the glass plate including the first main surface and a second main surface, the method including: a preparation step of preparing the glass plate; a conveying step of conveying a mist substance for forming the functional layer to a position facing the first main surface with use of a carrier gas; a supplying step of supplying the mist substance from the position facing the first main surface toward the first main surface; and a functional layer forming step of forming the functional layer on the first main surface.

According to this configuration, it is possible to form the functional layer on the first main surface of the glass plate with use of the mist substance by conveying the mist substance toward the first main surface of the glass plate with use of the carrier gas. Therefore, it is unnecessary to make a gas of a substance to be used to form the functional layer, and a mist that is made from a solution of the substance or a liquid obtained by dispersing powder of the substance therein, for example, can be applied to the formation of the functional layer on the first main surface. Since it is unnecessary to make a gas of the substance, the scope of substances applicable to the formation of the functional layer is expanded, and types of functional layers that can be formed on a glass plate can be increased.

It is preferable that, in the supplying step of the above configuration, the mist substance is supplied from a supply nozzle extending from the position facing the first main surface toward the first main surface, and a protective gas for protecting the mist substance is supplied along an inner wall surface of the supply nozzle in a direction from the position facing the first main surface toward the first main surface.

According to this configuration, the protective gas flows along the inner wall surface of the supply nozzle toward the first main surface of the glass plate. Therefore, the mist substance is guided toward the first main surface by the protective gas within the supply nozzle. Consequently, it is possible to prevent adhesion and agglomeration of the mist substance on the inner wall surface of the supply nozzle. Also, the protective gas can reduce an influence of the ambient temperature. Therefore, the mist substance can be kept from being affected by the ambient temperature while being supplied to the first main surface.

In the above configuration, it is preferable that the preparation step is a forming step of forming a molten raw material of the glass plate in a float bath when the glass plate is manufactured with use of a float method, and, in the supplying step, the mist substance is supplied toward the first main surface of the glass plate that is being formed in the forming step.

According to this configuration, it is possible to favorably form the functional layer in a production line of the float method, which is often applied as a glass manufacturing method.

In the above configuration, it is preferable that a temperature adjusting step of adjusting a temperature of the mist substance is performed in the conveying step.

The forming step in the float method is performed at a high temperature of about 600° C., for example. Therefore, when the temperature adjusting step is performed to cool the mist substance, evaporation of a solvent such as water contained in the mist is prevented, and the mist substance can be conveyed while being kept in the state of mist.

In the above configuration, it is preferable that the functional layer forming step includes a functional film forming step of forming a functional film on the first main surface with use of the mist substance as a raw material of the functional film or at least a part of a precursor of the raw material.

According to this configuration, it is possible to favorably form the functional film with use of the mist substance as the raw material or at least a part of the raw material.

In the above configuration, it is preferable that the functional film forming step is performed through mist chemical vapor deposition (CVD).

According to this configuration, it is possible to favorably form the functional film through the mist CVD.

In the above configuration, it is preferable that the functional layer forming step includes a modification step of forming the functional layer by modifying a portion of the glass plate constituting the first main surface with use of the mist substance.

According to this configuration, it is possible to favorably form the functional layer by modifying the portion of the glass plate constituting the first main surface with use of the mist substance.

A functional layer forming device according to the present invention is a functional layer forming device configured to be used in the above-described method for manufacturing a glass plate including a functional layer, the functional layer forming device including: a conveyance path configured to convey a mist substance for forming the functional layer to a position facing the first main surface with use of a carrier gas; and a supply nozzle communicating with the conveyance path and configured to supply the mist substance from the position facing the first main surface toward the first main surface.

With this configuration, it is possible to obtain a functional layer forming device with which the method for manufacturing a glass plate including a functional layer can be favorably performed.

In the above configuration, it is preferable that the supply nozzle includes a supply opening extending across an entire region of the supply nozzle in a width direction orthogonal to a direction in which the glass plate moves relative to the supply nozzle.

In this configuration, the supply nozzle includes the supply opening extending across the entire region of the supply nozzle in the width direction orthogonal to the direction in which the glass plate moves relative to the supply nozzle, and therefore, it is possible to supply the mist substance uniformly over an entire region of the glass plate in the width direction. Consequently, it is possible to form a uniform functional layer over the entire first main surface of the glass plate.

In the above configuration, it is preferable that the functional layer forming device further includes a protective gas supply means for supplying a protective gas for protecting the mist substance along an inner wall surface of the supply nozzle.

According to this configuration, the protective gas flows along the inner wall surface of the supply nozzle toward the first main surface of the glass plate. Therefore, the mist substance is guided toward the first main surface by the protective gas within the supply nozzle. Consequently, it is possible to prevent adhesion and agglomeration of the mist substance on the inner wall surface of the supply nozzle. Also, the protective gas can reduce an influence of the ambient temperature. Therefore, the mist substance can be kept from being affected by the ambient temperature while being supplied to the first main surface.

In the above configuration, it is preferable that the functional layer forming device further includes a heat medium jacket covering the conveyance path.

It is possible to adjust the temperature of the conveyance path by providing the heat medium jacket as in this configuration. Consequently, it is possible to prevent evaporation of a solvent such as water contained in the mist by cooling the conveyance path under a high-temperature condition, and keep the mist substance in the state of mist while conveying the mist substance. Also, the conveyance path can be warmed under a low-temperature condition to prevent agglomeration of the mist substance and keep the mist substance in the state of mist while conveying the mist substance. Note that, if the supplying step is executed under the low-temperature condition, it is possible to prevent agglomeration of the mist substance by warming the mist substance in the temperature adjusting step.

### BRIEF DESCRIPTION OF THE DRAWINGS

FIG. 1 is a diagram showing an embodiment of a production line of a glass plate including a functional layer.

FIG. 2 is a cross-sectional view showing an embodiment of a functional layer forming device.

FIG. 3 is a perspective view showing a main part of an embodiment of the functional layer forming device.

FIG. 4 is a flowchart showing a method for manufacturing a glass plate including a functional layer.

### DETAILED DESCRIPTION OF PREFERRED EMBODIMENTS

The following describes an embodiment of a method for manufacturing a glass plate 10 including a functional layer and a functional layer forming device according to the present invention with reference to the drawings. However, there is no limitation to the following embodiment, and various changes can be made without departing from the gist of the present invention.

### Glass Plate Production Line

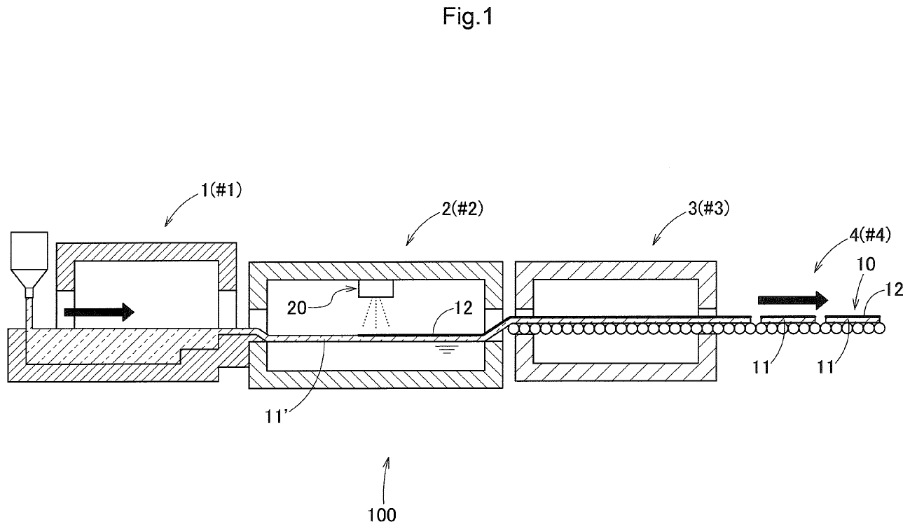

As shown in FIG. 1, a glass plate production line 100 includes a melting furnace 1, a float bath 2, an annealing lehr 3, a cutting device 4, and the like arranged in this order from the upstream side toward the downstream side, for example. Also, a functional layer forming device 20 is provided in the float bath 2, for example.

A molten raw material supplied from the melting furnace 1 to the float bath 2 is formed in the float bath 2. That is to say, the molten raw material is formed on molten tin in the float bath 2. In the float bath 2, a functional layer 12 is formed by the functional layer forming device 20 on a first main surface (upper surface) of a glass plate (glass ribbon 11′) that is being formed prior to being cut. Thereafter, the glass plate is annealed in the annealing lehr 3 and then cut to a predetermined length by the cutting device 4, and thus a glass plate 10 including the functional layer is manufactured. In the following description, the glass plate (glass ribbon 11′) prior to being cut, which includes the glass plate that is being formed in the float bath 2 and the glass plate that is being annealed in the annealing lehr 3, and the cut glass plate 11 may also be collectively referred to as “the glass plate 11”.

### Functional Layer Forming Device

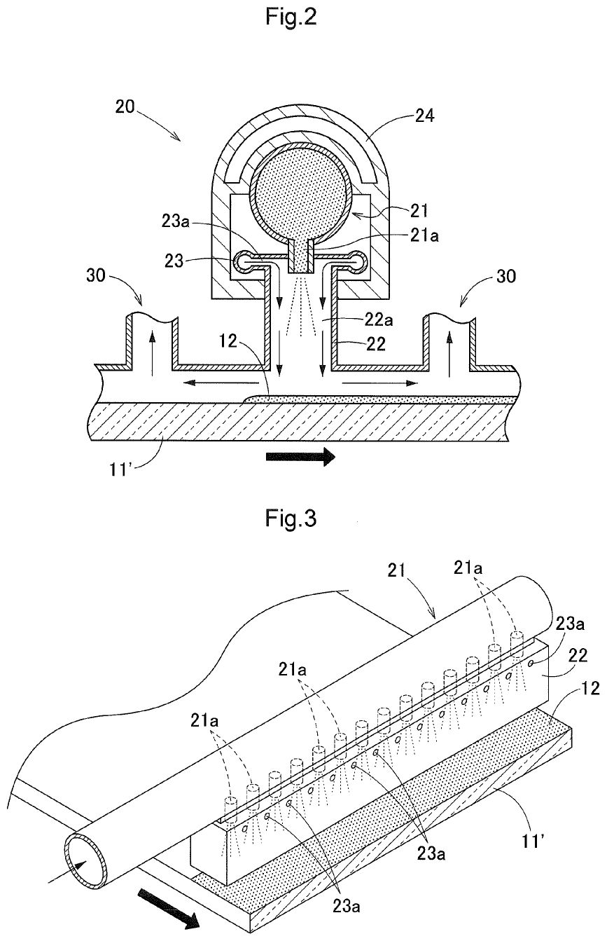

As shown in FIGS. 2 and 3, the functional layer forming device 20 includes a mist conveying path 21 (corresponding to a conveyance path) and a supply nozzle 22. The functional layer forming device 20 also includes a protective gas supply tube 23. The mist conveying path 21 and the protective gas supply tube 23 are covered with a water cooling jacket 24 (an example of a heat medium jacket). Note that a heat medium contained in the heat medium jacket is not limited to water, and may also be a medium other than water, such as an oil.

The mist conveying path 21 extends along a width direction of the glass plate 11 (a direction orthogonal to a conveying direction of the glass plate, i.e., a direction in which the glass plate moves relative to the supply nozzle 22).

The mist conveying path 21 is connected to a mist generating device (not shown). A mist substance for forming the functional layer 12, which has been generated in the mist generating device, is conveyed inside the mist conveying path 21 by a carrier gas. The mist substance is conveyed to a position facing the upper surface of the glass plate 11 (a position above the glass plate) that is being formed in the float bath 2.

The supply nozzle 22 extends along a longitudinal direction of the mist conveying path 21 under the mist conveying path 21. The supply nozzle 22 includes a single supply opening 22a extending across the glass plate 11 in the width direction (the direction orthogonal to the conveying direction of the glass plate 11). In the present embodiment, the supply opening 22a has a rectangular shape whose long sides extend along the width direction of the glass plate 11. The supply opening 22a extends across the glass plate 11 in the width direction of the glass plate 11.

Note that the supply opening 22a does not necessarily have to extend across the glass plate 11 in the width direction of the glass plate 11. Also, the number of supply openings 22a is not limited to one and may also be two or more. It is sufficient to adopt a configuration that makes it possible to uniformly supply the mist substance across the entire width of the glass plate 11.

A communication section via which the mist conveying path 21 communicates with the supply nozzle 22 is provided between the mist conveying path 21 and the supply nozzle 22. Communication paths 21a via which the mist conveying path 21 communicates with the supply nozzle 22 are formed in the communication section. The functional layer forming device includes the plurality of communication paths 21a in a longitudinal direction of the supply nozzle 22 (the width direction of the glass plate). That is to say, the communication paths 21a are disposed at equal intervals so as to be evenly arranged over the entire region of the supply nozzle 22 in the longitudinal direction. Since the communication paths 21a are evenly arranged over the entire region of the supply nozzle 22 in the longitudinal direction as described above, the mist substance can be evenly supplied irrespective of positions in the longitudinal direction of the supply opening 22a of the supply nozzle 22.

The protective gas supply tube 23 extends along the longitudinal directions of the mist conveying path 21 and the supply nozzle 22. In the present embodiment, two protective gas supply tubes 23 are respectively provided on the upstream side and the downstream side so as to sandwich the supply nozzle 22 in the conveying direction of the glass plate.

The supply nozzle 22 communicates with the protective gas supply tubes 23 via protective gas communication paths 23a. The functional layer forming device includes the plurality of protective gas communication paths 23a in the longitudinal direction of the supply nozzle 22 (the width direction of the glass plate 11). Here, the protective gas supply tubes 23 and the protective gas communication paths 23a correspond to a protective gas supply means. The protective gas communication paths 23a are disposed at equal intervals so as to be evenly arranged over the entire region of the supply nozzle 22 in the longitudinal direction. The protective gas communication paths 23a are provided at the same positions as the communication paths 21a in the longitudinal direction, for example. Note that the protective gas communication paths 23a do not necessarily have to be provided at the same positions as the communication paths 21a in the longitudinal direction, and may also be provided at positions different from the positions of the communication paths 21a in the longitudinal direction. The protective gas communication paths 23a are provided on the upstream side and the downstream side so as to sandwich the supply nozzle 22 in the conveying direction of the glass plate 11, for example. Note that the protective gas communication paths 23a may also be provided on only the upstream side or the downstream side of the supply nozzle 22 in the conveying direction of the glass plate 11.

The functional layer forming device also includes exhaust paths 30. In the present embodiment, the exhaust paths 30 are respectively provided at two positions on the upstream side and the downstream side so as to sandwich the supply nozzle 22 in the conveying direction of the glass plate 11. For example, exhaust fans are provided in the exhaust paths 30, and the carrier gas and a reaction residue of the mist substance are discharged via the exhaust paths 30 to the outside, for example.

The mist substance has a larger weight (specific gravity) per particle than gas. Therefore, if the mist substance is conveyed to the mist conveying path 21 with use of the carrier gas, for example, it is difficult to uniformly distribute the mist substance over the entire mist conveying path 21 in the longitudinal direction, and there arises a variation in a concentration distribution of the mist substance in the longitudinal direction of the mist conveying path 21. That is to say, if a flowing amount or a flowing rate of the carrier gas is increased to make the mist substance reach the farthest part of the mist conveying path, the concentration of the mist substance becomes low on the upstream side in a conveying direction of the mist substance.

Accordingly, if a tubular member constituting the mist conveying path 21 (corresponding to the conveyance path) is provided with a single communication path like a slit extending across the supply nozzle 22 in the longitudinal direction, the concentration of the mist substance cannot be made uniform in the longitudinal direction of the supply nozzle 22 and the thickness of the formed functional layer may be uneven.

Therefore, the plurality of communication paths 21a having a tubular shape are provided along the longitudinal direction of the mist conveying path 21 (supply nozzle 22) as shown in FIG. 3. Even if there is a variation in the concentration distribution of the mist substance immediately after the mist substance is sprayed from the communication paths 21a, the mist substance spreads concentrically due to the plurality of communication paths 21a having the tubular shape. Therefore, the distribution of the mist substance becomes uniform while the mist substance is passing through the supply nozzle 22, and the functional layer has a uniform thickness.

### Method for Manufacturing Glass Plate Including Functional Layer

The following describes an example of a method for manufacturing a glass plate including a functional layer according to the present invention, in which the functional layer is formed on the glass plate through online mist CVD. The online mist CVD is a method for performing mist CVD at the same time in a production line of the glass plate.

The following describes a float method, which is an example of a glass manufacturing process. As shown in FIG. 1, the method for manufacturing a glass plate with use of the float method includes a melting step (#1), a forming step (#2), an annealing step (#3), and a cutting step (#4), for example.

The melting step (#1) is a step of melting a raw material of the glass plate in the melting furnace 1. The forming step (#2) is a step of forming the molten raw material supplied from the melting furnace 1 to the float bath 2 on molten tin in the float bath 2. The annealing step (#3) is a step of annealing the glass plate 11 formed on the molten tin, in the annealing lehr 3. The cutting step (#4) is a step of cutting the annealed glass plate 11 to a predetermined length with use of the cutting device 4.

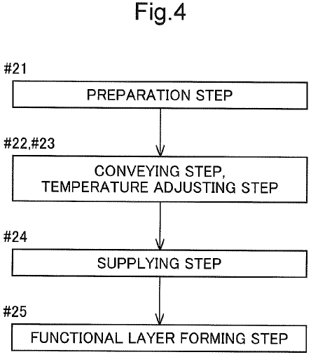

The method for manufacturing a glass plate including a functional layer according to the present invention can be performed in the forming step (#2), for example. As shown in FIG. 4, the method for manufacturing a glass plate including a functional layer according to the present invention includes a preparation step (#21), a conveying step (#22), a supplying step (#24), and a functional layer forming step (#25).

The preparation step (#21) is a step of preparing a glass plate. In the present embodiment, the preparation step is the forming step (#2) of forming the molten raw material of the glass plate 11 in the float bath 2 when the glass plate is manufactured with use of the float method.

The conveying step (#22) is a step of conveying a mist substance for forming the functional layer to a position facing the upper surface of the glass plate with use of a carrier gas.

The mist substance includes at least either a raw material substance that is used to form the functional layer through the mist CVD or a precursor of the raw material substance.

The raw material substance can be selected according to the functional layer to be formed. Although the raw material substance is not particularly limited, cobalt (III) acetylacetonate can be used as the raw material substance, for example.

The mist substance is produced by making a mist of an aqueous solution of the raw material substance described above. Note that it is also possible to make a mist of a solution other than an aqueous solution. For example, toluene or methanol can be used as a solvent other than water. Alternatively, it is also possible to make a mist of a dispersion liquid obtained by dispersing powder of the raw material substance in a liquid, rather than a solution.

The carrier gas is not particularly limited as long as the carrier gas can convey the mist substance. For example, an inert gas such as helium, nitrogen, or argon can be used.

Alternatively, it is also possible to use, as the carrier gas, a gas that reacts with the mist substance and forms a part of a raw material of the functional layer. Examples of the gas that reacts with the mist substance include hydrogen, oxygen, ozone, and ammonia. Alternatively, the carrier gas may be a mixture of an inert gas and a gas that reacts with the mist substance. As described above, the carrier gas is not limited to an inert gas. That

is to say, a gas that can convey the mist substance corresponds to the “carrier gas” in the present invention irrespective of whether or not the gas reacts with the mist substance.

The supplying step (#24) is a step of supplying the mist substance toward a first main surface of the glass plate from the position facing the upper surface. In the present embodiment, the mist substance conveyed through the mist conveying path 21 to the position facing the upper surface is supplied to the supply nozzle 22 via the communication paths 21a. The mist substance supplied to the supply nozzle 22 is supplied from the supply opening 22a to the upper surface of the glass plate. That is to say, in the present embodiment, the upper surface of the glass plate 11 that is floating on the molten tin and being formed corresponds to the first main surface, and a lower surface (a surface that is in contact with the molten tin) of the glass plate 11 corresponds to a second main surface.

In the present embodiment, the glass plate 11 is prepared in the preparation step (#21) in such a manner as to extend along a horizontal direction. Note that the state where the glass plate 11 “extends along a horizontal direction” is not limited to a state where the glass plate 11 extends horizontally, and it is sufficient that the first main surface and the second main surface of the glass plate 11 extend along a floor surface on which the production line 100 of the glass plate is installed. That is to say, the state where the glass plate 11 “extends along a horizontal direction” includes the state where the glass plate 11 extends horizontally and a state where the glass plate 11 slopes by 15° or less from the position where the glass plate 11 extends horizontally, for example.

In the supplying step (#24), a protective gas for protecting the mist substance is supplied along an inner wall surface of the supply nozzle 22 toward the first main surface (upper surface).

The protective gas is not particularly limited, and may be an inert gas such as helium, nitrogen, or argon, for example. Alternatively, it is also possible to use, as the protective gas, a gas that reacts with the mist substance and forms a part of a raw material of the functional layer. Examples of the gas that reacts with the mist substance include hydrogen, oxygen, ozone, and ammonia. Alternatively, the protective gas may be a mixture of an inert gas and a gas that reacts with the mist substance. The protective gas may be the same gas as the carrier gas or a gas different from the carrier gas.

The method for manufacturing a glass plate including a functional layer includes a temperature adjusting step (#23) in addition to the steps described above. The temperature adjusting step (#23) is a step of cooling the mist substance in the conveying step (#22). In the present embodiment, the mist conveying path 21 is covered with the water cooling jacket 24, and the mist substance is cooled while being conveyed through the mist conveying path 21 to suppress an increase in the temperature of the mist substance. Note that, if the supplying step (#22) is executed under a low-temperature condition, the mist substance may be warmed in the temperature adjusting step (#23). The functional layer forming step (#25) is a step of forming the

functional layer on the first main surface (upper surface) of the glass plate. In the present embodiment, a functional film is formed through the mist CVD. That is to say, the functional film is formed on the first main surface through a reaction between the raw material substance included in the mist substance and another raw material substance. That is to say, in the present embodiment, the functional layer forming step (#25) includes a functional film forming step of forming the functional film.

Examples of the functional film formed in the present embodiment include absorbing films such as a light absorbing film and optical control films such as an infrared reflective film, a UV cut film, a high reflective film, a low reflective film, a light scattering film, and a transparent conductive film. Furthermore, examples of the functional film (functional layer) include a semiconductor layer, an electricity transport layer and a hole transport layer for a solar cell, a band alignment layer, a buffer layer, a mechanically durable film, and a chemically durable film.

Thereafter, for example, the annealing step (#3) and the cutting step (#4) described above are performed as shown in FIG. 1, and thus the glass plate 10 including the functional layer is manufactured.

### Other Embodiments

Although an embodiment of the present invention has been described, the present invention is not limited to the above embodiment, and various changes can be made without departing from the gist of the present invention. Note that other embodiments described below can be combined as appropriate.
(1) In the above embodiment, a case is described as an example in which the functional film (functional layer) is formed on the first main surface of the glass plate through the mist CVD, but there is no limitation to this example. For example, a method other than the mist CVD, such as a sol-gel method, may also be applied as long as the functional film (functional layer) is formed on the first main surface with use of the mist substance.
(2) In the above embodiment, a case is described as an example in which the functional film is formed as the functional layer on the first main surface with use of the mist substance, but there is no limitation to this example. For example, the functional layer may be formed by modifying a portion of the glass plate constituting the first main surface with use of the mist substance. For example, the functional layer can be formed by modifying the portion of the glass plate constituting the first main surface with use of a mist of a hydrogen fluoride aqueous solution as the mist substance. That is to say, in this embodiment, the functional layer forming step (#25) includes a modification step of modifying the portion of the glass plate constituting the first main surface to form the functional layer.
(3) In the above embodiment, a case is described as an example in which the functional layer is formed in the float bath 2 (forming step) in the glass manufacturing process in which the float method is used, but there is no limitation to this example. For example, the functional layer may also be formed in a step other than the forming step, such as the annealing step (annealing lehr 3).
(4) In the above embodiment, a case is described as an example in which the functional layer is formed in the glass manufacturing process in which the float method is used, but there is no limitation to this example. For example, the functional layer may be formed in a step of a method for manufacturing glass other than the float method, such as a roll-out method or a fusion method.
(5) In the above embodiment, a case is described as an example in which the functional layer is formed on the glass plate extending along the horizontal direction, but there is no limitation to this example. For example, the functional layer may also be formed on a glass plate extending along an up-down direction. For example, when a glass plate is manufactured with use of the fusion method, the glass plate is formed in such a manner as to extend along the up-down direction. Therefore, by forming the functional layer on the glass plate extending along the up-down direction, it is possible favorably form the functional layer in a process of manufacturing the glass plate with use of the fusion method.
(6) In the above embodiment, a case is described as an example in which the functional layer is formed in a process of manufacturing the glass plate, such as the online mist CVD, but there is no limitation to this example. The functional layer may also be formed on the glass plate after the glass plate is manufactured.

### INDUSTRIAL APPLICABILITY

The present invention is widely applicable to a method for manufacturing a glass plate including a functional layer and a functional layer forming device.

### LIST OF REFERENCE SIGNS

10 Glass plate including functional layer
11 Glass plate
12 Functional layer
20 Functional layer forming device
21 Header tube (conveyance path)
22 Supply nozzle
22a Supply opening
23 Protective gas supply tube (protective gas supply means)
24 Water cooling jacket (heat medium jacket)
#21 Preparation step
#22 Conveying step
#23 Temperature adjusting step
#24 Supplying step
#25 Functional layer forming step

1. A method for manufacturing a glass plate including a functional layer in which the functional layer is formed on a first main surface of the glass plate including the first main surface and a second main surface, the method comprising:
a preparation step of preparing the glass plate;
a conveying step of conveying a mist substance for forming the functional layer to a position facing the first main surface with use of a carrier gas;
a supplying step of supplying the mist substance from the position facing the first main surface toward the first main surface; and
a functional layer forming step of forming the functional layer on the first main surface.

2. The method for manufacturing a glass plate including a functional layer according to claim 1,
wherein, in the supplying step, the mist substance is supplied from a supply nozzle extending from the position facing the first main surface toward the first main surface, and
a protective gas for protecting the mist substance is supplied along an inner wall surface of the supply nozzle in a direction from the position facing the first main surface toward the first main surface.

3. The method for manufacturing a glass plate including a functional layer according to claim 1,
wherein the preparation step is a forming step of forming a molten raw material of the glass plate in a float bath when the glass plate is manufactured with use of a float method, and
in the supplying step, the mist substance is supplied toward the first main surface of the glass plate that is being formed in the forming step.

4. The method for manufacturing a glass plate including a functional layer according to claim 3,
wherein a temperature adjusting step of adjusting a temperature of the mist substance is performed in the conveying step.

5. The method for manufacturing a glass plate including a functional layer according to claim 1,
wherein the functional layer forming step includes a film forming step of forming a functional film on the first main surface with use of the mist substance as a raw material of the functional film or at least a part of a precursor of the raw material.

6. The method for manufacturing a glass plate including a functional layer according to claim 5,
wherein the film forming step is performed through mist chemical vapor deposition.

7. The method for manufacturing a glass plate including a functional layer according to claim 1,
wherein the functional layer forming step includes a modification step of forming the functional layer by modifying a portion of the glass plate constituting the first main surface with use of the mist substance.

8. A functional layer forming device configured to be used in the method for manufacturing a glass plate including a functional layer according to claim 1, the functional layer forming device comprising:
a conveyance path configured to convey a mist substance for forming the functional layer to a position facing the first main surface with use of a carrier gas; and
a supply nozzle communicating with the conveyance path and configured to supply the mist substance from the position facing the first main surface toward the first main surface.

9. The functional layer forming device according to claim 8,
wherein the supply nozzle includes a supply opening extending across an entire region of the supply nozzle in a width direction orthogonal to a direction in which the glass plate moves relative to the supply nozzle.

10. The functional layer forming device according to claim 8, further comprising:
a protective gas supply means for supplying a protective gas for protecting the mist substance along an inner wall surface of the supply nozzle.

11. The functional layer forming device according to claim 8, further comprising:
a heat medium jacket covering the conveyance path.
